(19) United States
(12) Patent Application Publication
(10) Pub. No.: US 2006/0158212 A1
(43) Pub. Date: Jul. 20, 2006

(54) System for testing semiconductor devices

(75) Inventors: Christoph-Maria Schroeder, Inning am Holz (DE); Hans Schindlbeck, Munchen (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munchen (DE)

(21) Appl. No.: 11/311,419

(22) Filed: Dec. 20, 2005

(30) Foreign Application Priority Data
Dec. 21, 2004 (DE) 10 2004 061 549.7

(51) Int. Cl. G01R 31/26

(52) U.S. Cl. 324/765

(57) ABSTRACT

A testing system for testing semiconductor devices, in particular for testing the functioning of BGA semi-conductor devices incorporated in a semiconductor module, comprising an analyzer and at least one measuring adaptor for establishing the electric connections between the analyzer and the semiconductor device, wherein the measuring adaptor comprises a region with electric contact points via which electric pins of the semiconductor device can be contacted, and at least one electric coupling via which the measuring adaptor can be connected to the analyzer, wherein the electric contact points and the electric coupling of the measuring adaptor are connected with each other via at least one flexible flat cable.

### CLAIM FOR PRIORITY

This application claims the benefit of priority to German Application No. 10 2004 061 549.7, filed in the German language on Dec. 21, 2004, the contents of which are hereby incorporated by reference.

### TECHNICAL FIELD OF THE INVENTION

The present invention relates to a system for testing semiconductor devices, and in particular to a measuring adaptor for testing BGA semiconductor devices with BGA packages in a semiconductor module comprising a plurality of semiconductor devices.

### BACKGROUND OF THE INVENTION

In the present context, the term semiconductor devices refers, for instance, to integrated (analog or digital) computing circuits, as well as semiconductor memory devices such as functional memory devices (PLAs, PALs, etc.) and table memory devices such as ROMs or RAMs, in particular SRAMs and DRAMS. Frequently, a plurality of such semiconductor devices is combined with one another in semiconductor modules which are adapted to perform particular functions for logic data processing.

In semiconductor devices or semiconductor chips, respectively, integrated circuits have been established by numerous processes during the manufacturing, which are, for instance, in the case of logic semiconductor devices, capable of performing logic functions, i.e. of processing data in correspondence with predetermined operations, in particular pursuant to a programmed sequence. In a semiconductor device, e.g. a RAM (Random Access Memory) semiconductor memory chip, a plurality of memory cells are integrated, in which, by selective applying of a voltage, electric charge can be stored or read out as an information unit (bit).

Since as many memory cells as possible are intended to be accommodated in one memory device, one has been trying to realize same as simple as possible and on the narrowest space. The semiconductor devices are usually cast in a package of plastics from which project laterally arranged connection pins project. Via these connection pins, the semiconductor device may be contacted electrically with the periphery in that the connection pins are directly soldered with electric lines or are inserted into bases with appropriate plug connections.

So-called BGA (Ball Grid Array) semiconductor devices are also known, in which the electric pins for contacting the semiconductor device are designed on the top or bottom of the device package in the form of contact balls (ball pins). The ball pins are arranged in arrays or matrices (grid array) which are adapted to be contacted by placing and soldering with contact fields that designed complementarily or are arranged in laterally reversed manner, respectively. The ball pins on the top or bottom face of the package of the BGA semiconductor device also enable a plurality of semiconductor devices to be arranged one above the other in a stack (stacked modules), e.g. in the kind of so-called flip chips, and to be contacted among one another via the ball pins.

Usually, semiconductor devices are, in the course of the manufacturing process, in the semi-finished and/or finished state, prior to the incorporation in appropriate semiconductor modules, subject to extensive tests checking their functioning. By using appropriate test devices or analyzers, respectively, further tests may be performed after the incorporation of the semiconductor devices in the semiconductor modules (so-called module tests), so as to check the interaction of the individual semiconductor devices in the semiconductor module. Moreover, tests for analyzing errors may be required if a semiconductor assembly shows malfunctions after the assembly or during operation.

There have been known testing systems for performing module tests have been known which are connected via a plug to the normal interface of the semiconductor module. These conventional testing systems have the disadvantage that a semiconductor module can only be contacted via its outer contact points or pins while the individual semiconductor devices of the module cannot be examined separately. Therefore, with conventional test methods, it cannot, or only with a relatively great effort and with a test device having a very high measuring resolution, be determined that, for instance, an electric pin (contact ball) of a semiconductor device that is positioned inside the stack of semiconductor devices is contacted sufficiently well. In the known testing systems with known measuring adaptors it cannot, either, or only with relatively great effort, be determined whether there is a faultless interaction of a particular semiconductor device with other components of the semiconductor module. It is therefore desirable that the individual semiconductor devices of a semiconductor module can individually be subject to a functioning test while they are incorporated in the semiconductor module.

In the case of such module tests for error analysis, it is in particular intended to be determined whether the malfunction of the semiconductor module is caused by a particular semiconductor device. To this end, it is necessary to specifically contact a particular semiconductor device while it is interacting with the other components of the semiconductor module. Consequently, there must be established an electric connection between the semiconductor device incorporated in the semiconductor module and the above-mentioned test device or an analyzer, respectively, without modifying the rest of the semiconductor module.

With an arrangement of the semiconductor devices in one plane and the use of semiconductor devices with lateral pins, a separate contacting of a particular semiconductor device is relatively simply to realize since the connection pins projecting laterally from the package of the semiconductor device can be reached individually, for instance, from above the arrangement plane of the semiconductor module. The use of such semiconductor devices with lateral pins, however, has the disadvantage that the contact pins projecting at the border of the semiconductor package require much space, which is opposed to the efforts of miniaturization of the semiconductor modules.

As mentioned above, for lack of space and for increasing the number of semiconductor devices that can be incorporated in a semiconductor module, BGA semiconductor devices are used, the ball pins of which are contacted via appropriate connector bases at the bottom. It is, however, difficult to contact the electric pins or the ball pins, respectively, of the BGA semiconductor devices from outside since they are, due to the stacked arrangement, positioned between the BGA semiconductor devices and their connector bases.

Known testing systems or analyzers, respectively, are, as a rule, equipped with a measuring adaptor via which the electric connections between the contact pins of the semiconductor device to be tested and the analyzer are established. Document U.S. Pat. No. 6,081,429, for instance, discloses a measuring adaptor consisting of a rigid intermediate plate that is adapted to be arranged between two BGA semiconductor devices. On the rigid intermediate plate there are positioned electric conductor paths that establish the electric connections between the ball pins of the BGA semiconductor devices and the contact faces at the border of the intermediate plate. The dimensions of the intermediate plate have to be individually adapted to the dimensions of the semiconductor device to be tested such that the border of the intermediate plate projects over the edge of the BGA package of the semiconductor device. Thus, contact probes can be attached on the contact faces at the border of the rigid intermediate plate, said contact probes establishing an electric connection to the testing system.

Such measuring adaptors, on the one hand, have the disadvantage that the dimensions of the intermediate plate have to be adapted individually to those of the semiconductor device to be tested. On the other hand, the border of the intermediate plate projecting beyond the edge of the semiconductor device requires much space, which aggravates or renders it impossible to place the measuring adaptor between adjacent semiconductor devices in the case of a narrow arrangement without performing structural modifications of the semiconductor module. Moreover, the rigid construction of the intermediate plate prevents a flexible arrangement of the measuring adaptor.

### SUMMARY OF THE INVENTION

It is an object of the present invention to encounter the above-mentioned problems and disadvantages, and to provide a novel testing system with a measuring adaptor for the contacting and testing of semiconductor devices, in particular of BGA semiconductor devices with BGA packages in a semiconductor module that comprises a plurality of semiconductor devices. A further object of the present invention consists in minimizing the costs accruing by the test methods. Yet another object of the present invention consists in providing a novel contacting of BGA semiconductor devices incorporated in a semiconductor module without the necessity of performing structural modifications of the semiconductor module.

These and further objects are solved by the present invention by a system with the features defined in claim 1. Preferred embodiments of the invention are specified in the subclaims.

The present invention solves the above-mentioned objects by a testing system for testing semiconductor devices, in particular for testing the functioning of BGA semiconductor devices incorporated in a semiconductor module, comprising an analyzer and at least one measuring adaptor for establishing the electric connections between the analyzer and the semiconductor device, wherein the measuring adaptor comprises a region with electric contact points via which electric pins of the semiconductor device can be contacted, and at least one electric coupling via which the measuring adaptor can be connected to the analyzer; in accordance with the invention, the measuring adaptor is characterized in that the electric contact points and the electric coupling of the measuring adaptor are connected with each other via at least one flexible flat cable.

The present invention thus solves the problem of the limited space available in the semiconductor module and at the semiconductor devices to be examined. By the flexible design of the electric connection between the measuring adaptor and the pins to the test device or to the analyzer, respectively, via a flat cable, it is easier to place the measuring adaptor in the semiconductor module without structural modifications of the semiconductor module having to be performed. The use of flexibly bendable flat cables between the measuring adaptor and the pins to the analyzer enables a variable laying of these connecting lines. This way, the connecting lines between the measuring adaptor and the pins to the analyzer can also be guided out between closely adjacent semiconductor devices. Another advantage of the inventive measuring adaptor for a testing system consists in that it is of larger height and thus tops adjacent devices of the semiconductor module, so that a semiconductor device to be tested which is connected to the inventive measuring adaptor is easier accessible within the semiconductor module.

The inventive measuring adaptor further has the advantage that the ball pins of the semiconductor device with BGA package to be tested are adapted to be directly contacted; their electric contacts are otherwise only difficult to access in the incorporated state. This way, a direct error analysis can be performed at a semiconductor device to be tested while the semiconductor device concerned is incorporated in the semiconductor module and is in the operative state. Thus, the correct interaction of the semiconductor device to be tested with the remaining semiconductor devices and with other components in the semiconductor module can in particular be examined.

In a preferred embodiment of the present invention, the electric contact points and the electric coupling of the measuring adaptor are connected with each other via a number of flexible flat cables that are preferably arranged one on top of the other. The use of a plurality of easily bendable flat cables ensures a sufficient number of electric lines to connect the electric contact points and the electric coupling of the measuring adaptor with each other and to thus establish a connection of the electric pins of the semiconductor device to be tested with the analyzer. It is in particular an arrangement of a plurality of flexible flat cables in a plurality of layers one on top of the other that enables a space-saving solution of the above-mentioned objects without substantially impairing the flexibility of the electric connection between the contact points and the coupling of the measuring adaptor.

In accordance with a further preferred embodiment of the present invention, the number of flat cables can be connected to the analyzer via at least one common electric coupling. This way, the measuring adaptor can be connected with the analyzer via a common electric coupling irrespective of the number of flat cables used.

It is particularly advantageous if the flexible flat cables are designed as a flat film or as a plastic ribbon on which the electric conductor paths which establish the electric connection between the electric contact points and the electric coupling of the measuring adaptor are, for instance, applied by means of a lithography method. Such flat cables are also known as PCBs (printed circuit boards) and stand out by a particularly flat dimension and by high flexibility.

Expediently, the electric contact points of the measuring adaptor are arranged in a complementary or laterally reversed manner to the arrangement of electric pins of a semiconductor device to be tested, or in a complementary or laterally reversed manner to the arrangement of ball pins of a BGA semiconductor device to be tested. Thus, the region with the electric contact points of the measuring adaptor can be arranged between the BGA semiconductor device to be tested in an easy manner before it is incorporated in the semiconductor module, wherein the corresponding electric contacts of the BGA semiconductor device to be tested are connected with the contact points of the measuring adaptor and simultaneously with the corresponding pins of the semiconductor module.

To ensure a differentiated complete signal analysis of the semiconductor device to be tested by the analyzer, the flat cable comprises—for each electric pin of the semiconductor device to be tested or for each ball pin of the BGA semiconductor device to be tested, respectively—a separate conductor path which connects the corresponding contact point of the measuring adaptor with the electric coupling of the measuring adaptor. For a complete signal analysis it is expedient if all electric pins of the semiconductor device to be tested or all ball pins of the BGA semiconductor device to be tested, respectively, are adapted to be connected to the analyzer via the measuring adaptor.

In a further preferred embodiment of the present invention, the region with the electric contact points and/or the electric coupling of the measuring adaptor are arranged on the flat cable. Thus, the flat cable may be equipped cheaply already during manufacturing with the required contact points for the contacting of the electric pins of the semiconductor device to be tested and the electric coupling for the connection with the analyzer. This happens, for instance, by the manufacturing of a printed circuit board, wherein the above-mentioned components are taken into consideration in the exposure mask used for generating the electroconductive regions and the conductor paths.

It is particularly advantageous if the electric coupling of the measuring adaptor comprises a plug connection via which the measuring adaptor can be connected to the analyzer. This plug connection or the electric coupling of the measuring adaptor, respectively, may, for instance, be designed as SMD (Surface Mount Device) component, and in particular as MICTOR plug which is used as a common standard with plug connections in the present context. Thus, a quick and simple connection can be established between the measuring adaptor and the analyzer of the testing system. The measuring adaptor may also be equipped with a plurality of electric couplings for connecting the measuring adaptor with the analyzer or with a plurality of MICTOR plugs, respectively.

In yet another preferred embodiment, the testing system comprises a plurality of measuring adaptors, so that a number of semiconductor devices in one or in a plurality of semiconductor modules can be contacted simultaneously and tested in parallel.

Additionally, the measuring adaptor may be equipped with at least one further flat cable via which, for instance, an external current supply or the grounding, respectively, is provided, and/or the jumper setting of the semiconductor device to be tested can be adjusted. Thus, the semiconductor device to be tested can be supplied with the connections necessary for operation solely via the measuring adaptor, and the desired jumper setting of the semiconductor device to be tested can be performed at the measuring adaptor.

For better accessibility, the flat cable(s) for the electric connection between the electric contact points and the electric coupling of the measuring adaptor are arranged at an angle of preferably 90° vis-à-vis the flat cable for current supply, grounding, and/or jumper setting of the semiconductor device to be tested. For the purpose of a simple manufacturing, the flat cables for the electric connection between the electric contact points and the electric coupling of the measuring adaptor are formed integrally on a film with a flat cable for current supply, grounding, and/or jumper setting of the semiconductor device to be tested.

It is particularly advantageous if the inventive measuring adaptor comprises a connector base via which, in particular, the electric pins or ball pins of BGA semiconductor devices are contactable and are connected with the semiconductor module. The bottom of the connector base is therefore fully compatible with the bottom of the semiconductor device to be incorporated with the measuring adaptor in the semiconductor module or to be tested, respectively.

The connector base expediently has such a height that a semiconductor device to be tested which is incorporated with the measuring adaptor in the semiconductor module tops adjacent components of the semiconductor module. Since the semiconductor device to be tested is positioned upon the connector base of the measuring adaptor, it lies above the arrangement plane of the semiconductor module and thus above the adjacent components of the semiconductor module. Thus, the flat cables, for establishing the connection between the measuring adaptor and the analyzer, can be laid out of the plane of the electric pins or the ball pins of the semiconductor device to be tested across adjacent components of the semiconductor module without deflections.

Additionally, the connector base of the measuring adaptor may be composed of at least two parts that are preferably adapted to be stacked one on top of the other, and that each comprise flush holes for contacting the electric pins or the ball pins of the semiconductor device to be tested. The measuring adaptor is, as a rule, made of a plastic material in which a plurality of closely adjacent holes with small diameters for contacting the electric pins or the ball pins of the semiconductor device to be tested have to be provided.

The forming of closely adjacent holes with small diameters can be performed the easier, the smaller the distance to be bored is. In order to provide a connector base with sufficient height for the inventive measuring adaptor, it is therefore of advantage to compose it of a number of parts that are adapted to be stacked one on top of the other, in which separate holes for contacting the electric pins or the ball pins of the semiconductor device to be tested are each provided with a small boring distance. This way, a more favorable relation between the hole diameter and the boring distance is achieved during manufacturing. Subsequently, the parts that are adapted to be stacked one on top of the other can be composed to form a connector base, wherein the holes in the parts of the connector base are flush and thus each constitute continuous holes.

Although the present invention is described in conjunction with a testing system for testing the functioning of semiconductor devices, the inventive features substantially relate to the measuring adaptor itself. Independent claim 17 therefore claims protection for a measuring adaptor as such, which is adapted to be used in a testing system having the features described here.

### BRIEF DESCRIPTION OF THE DRAWINGS

In the following, the invention will be described by means of preferred embodiments, making reference to the enclosed drawing. The drawing shows:

FIG. 1 a schematic lateral representation of a measuring adaptor for a testing system according to a preferred embodiment of the present invention;

FIG. 2 a schematic bottom representation of a measuring adaptor for a testing system according to a preferred embodiment of the present invention; and

FIG. 3 a schematic view of the plane of the flat cables that are used in a measuring adaptor for a testing system according to a preferred embodiment of the present invention.

### DETAILED DESCRIPTION OF THE INVENTION

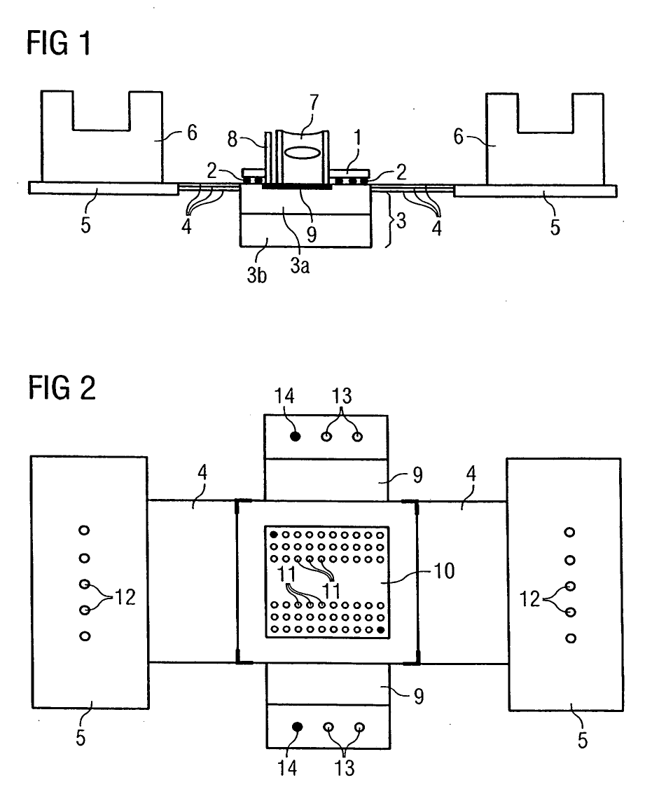

FIG. 1 shows a schematic lateral representation of a measuring adaptor that is adapted to be used in a testing system according to a preferred embodiment of the present invention. The semiconductor device to be tested is a BGA semiconductor device 1 with a BGA package, at the bottom of which there are formed a number of electric pins in the form of contact balls or ball pins 2 for contacting the semiconductor device 1. These ball pins 2 are arranged in arrays or matrices (grid array) and are contacted, by placing and soldering, with a contact field that is formed in a complementary or laterally reversed manner in a connector base 3 via which the BGA semi-conductor device 1 is incorporated in a semiconductor module (not illustrated).

The connector base of the measuring adaptor is composed of two parts 3a and 3b that are adapted to be stacked one on top of the other and that each comprise flush holes for contacting the electric pins or the ball pins of the semiconductor device to be tested. The top of the part 3a of the connector base 3 is compatible with the electric pins or ball pins 2 at the bottom of the semiconductor device 1. The bottom of the part 3b of the connector base 3 is compatible with the bottom of the semiconductor device 1 to be incorporated with the measuring adaptor in the semiconductor module.

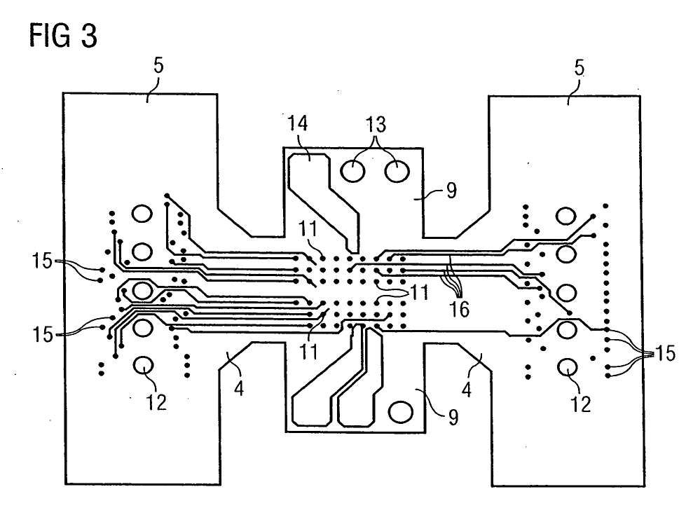

Between the connector base 3 and the BGA semiconductor device 1 there extend a number of flat cables 4 which extend outwardly to a free end. At their free ends, the flat cables 4 each comprise electric couplings 5 equipped with a MICTOR plug 6. On the flat cables 4 there are arranged conductor paths that will be described in more detail in connection with FIG. 3. The conductor paths connect the electric pins 2 of the semiconductor device 1 with the electric couplings 5. Thus, the electric pins 2 of the semiconductor device 1 are connected with an analyzer (not illustrated) via a connecting cable plugged into the plug connection 6 at the electric couplings 5 while the semiconductor device 1 interacts in parallel with the semiconductor module.

Since the BGA semiconductor devices 1, as a rule, comprise a large number of ball pins 2, they cannot be connected with the analyzer by one plane of flat cables 4 only, but a plurality of planes or layers of flat cables 4 are necessary, e.g. as in the embodiment illustrated in FIG. 1, 3 layers of flat cables 4 so as to contact all the pins of the semiconductor device 1 to be tested. Each layer of flat cables 4 contacts respectively different electric pins 2 of the semiconductor device 1 to be tested and connects them via conductor paths with correspondingly different connection points at the electric couplings 5 of the flat cables 4.

In addition to the flat cables 4 for the electric connection between the ball pins 2 of the semiconductor device 1 to be tested and the electric coupling 5 of the measuring adaptor, further flat cables 9 are additionally provided, via which the current supply, the grounding, and the jumper setting of the semiconductor device 1 may be performed. To this end, jumpers and a ground connection are provided on the further flat cables 9. The further flat cables 9 are arranged at an angle of 90° vis-à-vis the flat cables 4, so that the flat cables 4 extend in the paper plane of FIG. 1, and the flat cables 9 perpendicularly thereto.

FIG. 2 shows a schematic bottom representation of the measuring adaptor of FIG. 1 for a testing system according to a preferred embodiment of the present invention. It reveals that the flat cables 4 comprises, in a region 10 in which the BGA semiconductor device 1 to be tested is applied, a number of electroconductive contact points 11 that are arranged in a complementary or laterally reversed manner to the arrangement of the ball pins 2 at the bottom of the semiconductor device 1.

By placing the semiconductor device 1 with the measuring adaptor in the region 10, the ball pins 2 at the bottom of the semiconductor device 1 are electrically connected with the contact points 11. With this region 10 the measuring adaptor is also applied or soldered, respectively, on the connector base 3 so as to incorporate the BGA semiconductor device 1 together with the measuring adaptor in the semiconductor module. During the testing operation, the region 10 of the measuring adaptor consequently is being placed between the BGA semiconductor device 1 to be tested and the connector base 3. This way, the signals exchanged between the semiconductor module and the corresponding BGA semiconductor device 1 via the connector base 3 can be tapped in parallel by the measuring adaptor and be transmitted to the analyzer without disturbing the interaction between the semiconductor device 1 and the semiconductor module.

The conductor paths cannot be seen in this view since they are positioned at the top of the flat cables 4. The flat cables extend from the region 10 with the contact points 11 to their free ends 5 that are provided with fixing holes 12 so as to fix SMD devices or the MICTOR plug 6, respectively, to the measuring adaptor.

The further flat cables 9, at the free ends of which there are provided pins 13 and 14 for current supply, grounding, and jumper setting of the BGA semiconductor device 1, extend perpendicularly to the flat cables 4 from the region 10 in which the BGA semiconductor device 1 is applied or soldered, respectively, on the measuring adaptor.

FIG. 3 shows a schematic top view of the plane of the flat cables as they are used in a measuring adaptor for a testing system according to a preferred embodiment of the present invention. The joint view of FIGS. 2 and 3 reveals that the contact points 11 are, in the region 10 in which the BGA semiconductor device 1 to be tested is applied or soldered, respectively, on the measuring adaptor, continuous from the one side through to the other side of the flat cable. Thus, the electric pins 2 of the BGA semiconductor device 1 are connected both with the contact points 11 of the measuring adaptor and with the electric pins of the connector base 3, i.e. the electric pins 2 of the BGA semiconductor device 1 are contacted through to the connector base 3 via the contact points 11 of the measuring adaptor.

On the top of the flat cables 4 and 9 illustrated in FIG. 3, there extend conductor paths 16 connecting the contact points 11 with connection points 15 on the coupling 5 at the free end of the flat cable 4. The connection points 15 at the free end of the flat cable 4 are connected with a MICTOR plug 6 that is also positioned on the top illustrated in FIG. 3 at the free ends of the flat cable 4, but is not illustrated in FIG. 3 for better overview. The MICTOR plug 6 or another device for the electric coupling of the measuring adaptor with the analyzer can be fixed to the free ends 5 of the flat cables 4 via the fixing holes 12.

On the further flat cable 9 there are positioned connection points 13 and 14 for current supply, grounding, and jumper setting of the semiconductor device 1 to be tested. The flat cables 4 for the electric connection between the electric contact points 11 and the electric coupling 6 of the measuring adaptor are, together with the further flat cable 9 for current supply, grounding, and/or jumper setting of the semi-conductor device 1 to be tested, and the region 10 for placing or soldering, respectively, of the semiconductor device 1 to be tested, formed integrally on a flexibly bendable plastic substrate.

For manufacturing the flat cables 4 and 9, the electric contact points 11, the connection points 15 at the free ends of the flat cables 4, the conductor paths 16, and the connection points 13 and 14 for current supply, grounding, and jumper setting of the semiconductor device 1 to be tested, may be applied on the flexible plastic substrate in the form of a printed circuit board (PCB) by means of a lithography method, wherein the representation in FIG. 1 may be used as an exposure mask for a plane of flat cables 4, 9. If further planes of flat cables 4, 9 are available in the measuring adaptor, they have to be produced with differing exposure masks since they connect respectively different electric pins 2 of the semiconductor device 1 to be tested with corresponding connection points 15 at the free ends of the flat cables 4 via conductor paths 16.

The measuring adaptor or the testing system according to the present invention can thus be used in semiconductor modules whose components are arranged on the narrowest space. By the use of flexible flat cables 4 and 9 for the electric connection between the measuring adaptor and the pins to the test device or to the analyzer, respectively, the measuring adaptor can be placed in the semiconductor module without structural modifications of the semiconductor module having to be performed. In addition, by the use of a connector base 3 with appropriate height, the semiconductor device 1 to be tested can be taken to a position above the adjacent components of the semiconductor module and is thus easier accessible. Due to the flexibility of the flat cables 4 and 9 between the measuring adaptor and the pins to the analyzer, these connecting lines between the semiconductor device 1 to be tested and the directly adjacent semiconductor device can be laid flexibly even if the measuring adaptor has its contact region 10 in a lower plane than the top package borders of the semiconductor devices of the corresponding semiconductor module.

What is claimed is:

1. A testing system for testing semiconductor devices (1), in particular for testing the functioning of BGA semiconductor devices (1) incorporated in a semiconductor module, comprising an analyzer and at least one measuring adaptor for establishing the electric connections between the analyzer and the semiconductor device (1), wherein the measuring adaptor comprises a region (10) with electric contact points (11) via which electric pins (2) of the semiconductor device (1) can be contacted, and at least one electric coupling (5, 6) via which the measuring adaptor can be connected to the analyzer, wherein the electric contact points (11) and the electric coupling (5, 6) of the measuring adaptor are connected with each other via at least one flexible flat cable (4).

2. The testing system according to claim 1, wherein said electric contact points (11) and said electric coupling (5, 6) of the measuring adaptor are connected with each other via a number of flexible flat cables (4) that are preferably arranged one on top of the other.

3. The testing system according to claim 1, wherein the number of flat cables (4) can be connected to the analyzer via at least one common electric coupling (5, 6).

4. The testing system according to claim 1, wherein said electric contact points (11) of the measuring adaptor are arranged in a complementary or laterally reversed manner to the arrangement of electric pins (2) of a semiconductor device (1) to be tested, or in a complementary or laterally reversed manner to the arrangement of ball pins (2) of a BGA semiconductor device (1) to be tested.

5. The testing system according to claim 1, wherein all electric pins (2) of a semiconductor device (1) to be tested, or all ball pins (2) of a BGA semiconductor device (1) to be tested, can be connected to the analyzer via the measuring adaptor.

6. The testing system according to claim 1, wherein said flexible flat cable (4) is designed as a flat film or as a plastic ribbon, respectively, or as a printed circuit board (PCB) with electric conductor paths (16) which establish the electric connection between the electric contact points (2) and the electric coupling (5, 6) of the measuring adaptor.

7. The testing system according to claim 6, wherein the flat cable(s) each comprise(s), for each electric pin (2) of a semiconductor device (1) to be tested, or for each ball pin (2) of a BGA semiconductor device (1) to be tested, a separate conductor path (16) connecting the corresponding contact point (11) of the measuring adaptor with the electric coupling (5, 6) of the measuring adaptor.

8. The testing system according to claim 1, wherein said region (10) with said electric contact points (11) and/or said electric coupling (5, 6) of the measuring adaptor are arranged on said flat cable (4).

9. The testing system according to claim 1, wherein said electric coupling (5) of the measuring adaptor comprises a plug connection (6) via which the measuring adaptor can be connected to the analyzer.

10. The testing system according to claim 1, wherein said electric coupling (5) of the measuring adaptor is designed as SMD component or MICTOR plug (6).

11. The testing system according to claim 1, wherein the testing system is equipped with a number of measuring adaptors, so that a plurality of semiconductor devices (1) in a semiconductor module and/or a plurality of semiconductor devices (1) in a plurality of semiconductor modules can be tested in parallel.

12. The testing system according to claim 1, wherein the testing system comprises at least one further flat cable (9) via which, for instance, the current supply or the grounding can be provided, and/or jumper settings of the semiconductor device (1) to be tested can be adjusted.

13. The testing system according to claim 12, wherein the flat cable(s) for the electric connection between said electric contact points (11) and said electric coupling (5, 6) of the measuring adaptor is/are arranged at an angle of preferably 90° vis-à-vis said flat cable (9) for current supply, grounding, and/or jumper setting of the semiconductor device (1) to be tested.

14. The testing system according to claim 12, wherein at least one flat cable (4) for the electric connection between said electric contact points (11) and said electric coupling (5, 6) of the measuring adaptor is formed integrally with a flat cable (9) for current supply, grounding, and/or jumper setting of the semiconductor device (1) to be tested.

15. The testing system according to claim 1, wherein the measuring adaptor comprises a connector base (3), in particular for BGA semiconductor devices, said connector base (3) preferably having such a height that a semiconductor device (1) to be tested and incorporated in the semiconductor module and connected to the measuring adaptor tops adjacent components of the semiconductor module.

16. The testing system according to claim 15, wherein said connector base (3) of the measuring adaptor is composed of at least two parts (3a, 3b) adapted to be stacked one on top of the other, which each comprise flush holes for contacting the electric pins or the ball pins (2), respectively, of the semiconductor device (1) to be tested.

17. A measuring adaptor that is adapted to be used in a testing system comprising the features according to claim 1.
